(19) United States
(12) Patent Application Publication
(10) Pub. No.: US 2026/0101472 A1
(43) Pub. Date: Apr. 9, 2026

(54) COLD PLATE, COLD PLATE ASSEMBLY AND MOTHERBOARD MODULE

(71) Applicant: Wiwynn Corporation, New Taipei City (TW)

(72) Inventors: Hao-Jhan Hong, New Taipei City (TW); Wen An CHEN, New Taipei City (TW); Tsung-Yi Chen, New Taipei City (TW); Yi Cheng, New Taipei City (TW); Tsung-Han Li, New Taipei City (TW); Yan Yu CHEN, New Taipei City (TW)

(21) Appl. No.: 19/344,624

(22) Filed: Sep. 30, 2025

Related U.S. Application Data
(60) Provisional application No. 63/703,251, filed on Oct. 4, 2024.

(30) Foreign Application Priority Data
Jul. 23, 2025 (TW) 114127973

(51) Int. Cl. H05K 7/20; H05K 1/02

(52) U.S. Cl. CPC H05K 7/20254; H05K 1/0203; H05K 7/20272; H05K 7/20436; H05K 7/20772; H05K 2201/066

(57) ABSTRACT

A cold plate includes a main inlet channel, a sub-inlet channel, a heat exchange chamber, a sub-outlet channel and a main outlet channel. The sub-inlet channel is in fluid communication with the main inlet channel. The heat exchange chamber is in fluid communication with the sub-inlet channel. The sub-outlet channel is in fluid communication with the heat exchange chamber. The main outlet channel is in fluid communication with the sub-outlet channel. The cold plate has a first side and a second side located opposite to each other, a cold fluid inlet of the main inlet channel and a hot fluid outlet of the main outlet channel are located on the first side, and a cold fluid outlet of the main inlet channel and a hot fluid inlet of the main outlet channel are located on the second side.

### CROSS-REFERENCE TO RELATED APPLICATIONS

This non-provisional application claims priority under 35 U.S.C. § 119(a) on Provisional Application No(s). 63/703,251 filed in U.S.A. on Oct. 4, 2024, and Patent Application No(s). 114127973 filed in Taiwan, R.O.C. on Jul. 23, 2025, the entire contents of which are hereby incorporated by reference.

### TECHNICAL FIELD

The disclosure relates to a cold plate, a cold plate assembly, and a motherboard module.

### BACKGROUND

With the increasing heat generation of heat-generating components (such as central processing units or graphics processing units) in servers, cold plates have been adopted to be thermally coupled to the heat-generating components, and coolant flowing through the cold plate can carry away the heat conducted from the heat-generating components to the cold plate.

Generally, a T-shaped connector is provided on the top of the cold plate to connect to pipes for introducing/discharging coolant into/out of the cold plate. However, since servers are installed in racks with limited height, it is difficult to accommodate cold plates if their heights are excessive. Accordingly, how to address the aforementioned issue is one of the topics in this field.

### SUMMARY

The disclosure provides a cold plate, a cold plate assembly and a motherboard module, which enable the cold plate to be disposed in an internal space of a server.

One embodiment of the disclosure provides a cold plate. The cold plate includes a main inlet channel, a sub-inlet channel, a heat exchange chamber, a sub-outlet channel and a main outlet channel. The main inlet channel has a cold fluid inlet and a cold fluid outlet. The sub-inlet channel is in fluid communication with the main inlet channel. The heat exchange chamber is in fluid communication with the sub-inlet channel. The sub-outlet channel is in fluid communication with the heat exchange chamber. The main outlet channel is in fluid communication with the sub-outlet channel and has a hot fluid inlet and a hot fluid outlet. The cold plate has a first side and a second side located opposite to each other, the cold fluid inlet of the main inlet channel and the hot fluid outlet of the main outlet channel are located on the first side of the cold plate, and the cold fluid outlet of the main inlet channel and the hot fluid inlet of the main outlet channel are located on the second side of the cold plate.

Another embodiment of the disclosure provides a cold plate assembly. The cold plate assembly includes a first cold plate and a second cold plate. The first cold plate and the second cold plate each includes a main inlet channel, a sub-inlet channel, a heat exchange chamber, a sub-outlet channel and a main outlet channel. The main inlet channel has a cold fluid inlet and a cold fluid outlet. The sub-inlet channel is in fluid communication with the main inlet channel. The heat exchange chamber is in fluid communication with the sub-inlet channel. The sub-outlet channel is in fluid communication with the heat exchange chamber. The main outlet channel is in fluid communication with the sub-outlet channel and has a hot fluid inlet and a hot fluid outlet. Each of the first cold plate and the second cold plate has a first side and a second side located opposite to each other, the cold fluid inlet of the main inlet channel and the hot fluid outlet of the main outlet channel are located on the first side, and the cold fluid outlet of the main inlet channel and the hot fluid inlet of the main outlet channel are located on the second side. The main inlet channel of the first cold plate is in fluid communication with the main inlet channel of the second cold plate, and the main outlet channel of the first cold plate is in fluid communication with the main outlet channel of the second cold plate.

Still another embodiment of the disclosure provides a motherboard module. The motherboard module includes a motherboard and a cold plate assembly. The motherboard includes a circuit board, a first heat source and a second heat source which are disposed on the circuit board. The cold plate assembly includes a first cold plate and a second cold plate. Each of the first cold plate and the second cold plate includes a main inlet channel, a sub-inlet channel, a heat exchange chamber, a sub-outlet channel and a main outlet channel. The main inlet channel has a cold fluid inlet and a cold fluid outlet. The sub-inlet channel is in fluid communication with the main inlet channel. The heat exchange chamber is in fluid communication with the sub-inlet channel. The sub-outlet channel is in fluid communication with the heat exchange chamber. The main outlet channel is in fluid communication with the sub-outlet channel and has a hot fluid inlet and a hot fluid outlet. Each of the first cold plate and the second cold plate has a first side and a second side located opposite to each other, the cold fluid inlet of the main inlet channel and the hot fluid outlet of the main outlet channel are located on the first side, and the cold fluid outlet of the main inlet channel and the hot fluid inlet of the main outlet channel are located on the second side. The main inlet channel of the first cold plate is in fluid communication with the main inlet channel of the second cold plate, and the main outlet channel of the first cold plate is in fluid communication with the main outlet channel of the second cold plate.

According to the cold plate, the cold plate assembly and the motherboard module as discussed in the above embodiments, the cold plate has the first side and the second side located opposite to each other, the cold fluid inlet of the main inlet channel and the hot fluid outlet of the main outlet channel are located on the first side of the cold plate, and the cold fluid outlet of the main inlet channel and the hot fluid inlet of the main outlet channel are located on the second side of the cold plate. The aforementioned configuration can reduce the overall height of the cold plate, making it suitable for installation within an internal space of a server.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of a motherboard module according to some embodiments of the disclosure;

FIG. 2 is an exploded view of a motherboard module according to some embodiments of the disclosure;

FIG. 3 is a partial cross-sectional view of a motherboard and a first cold plate according to some embodiments of the disclosure;

FIG. 4 is a cross-sectional view of a first cold plate according to some embodiments of the disclosure;

FIG. 5 is a partial cross-sectional view of a motherboard and a second cold plate according to some embodiments of the disclosure;

FIG. 6 is a cross-sectional view of a second cold plate according to some embodiments of the disclosure;

FIG. 7 is a side view of a motherboard module according to some embodiments of the disclosure;

FIG. 8 is a cross-sectional view of a cold plate according to some embodiments of the disclosure;

FIG. 9 is another cross-sectional view of a cold plate according to some embodiments of the disclosure; and

FIG. 10 is another cross-sectional view of a cold plate according to some embodiments of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

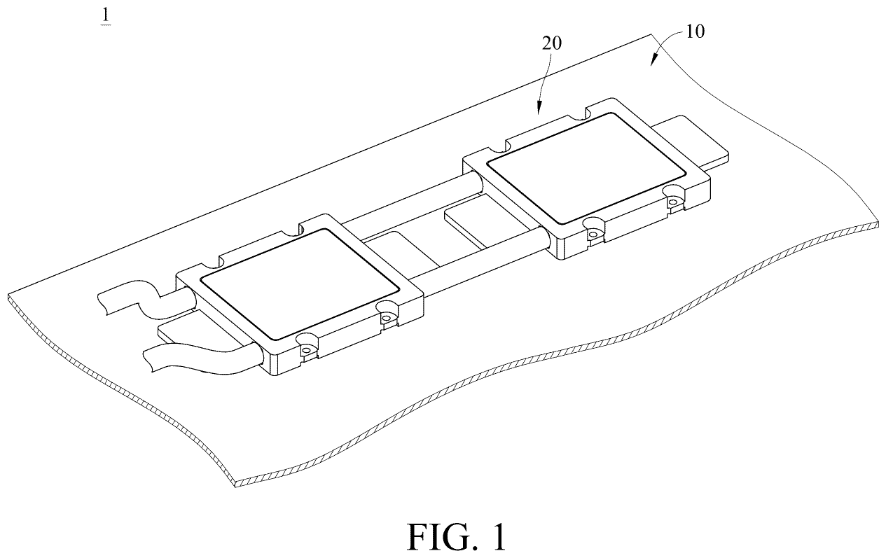

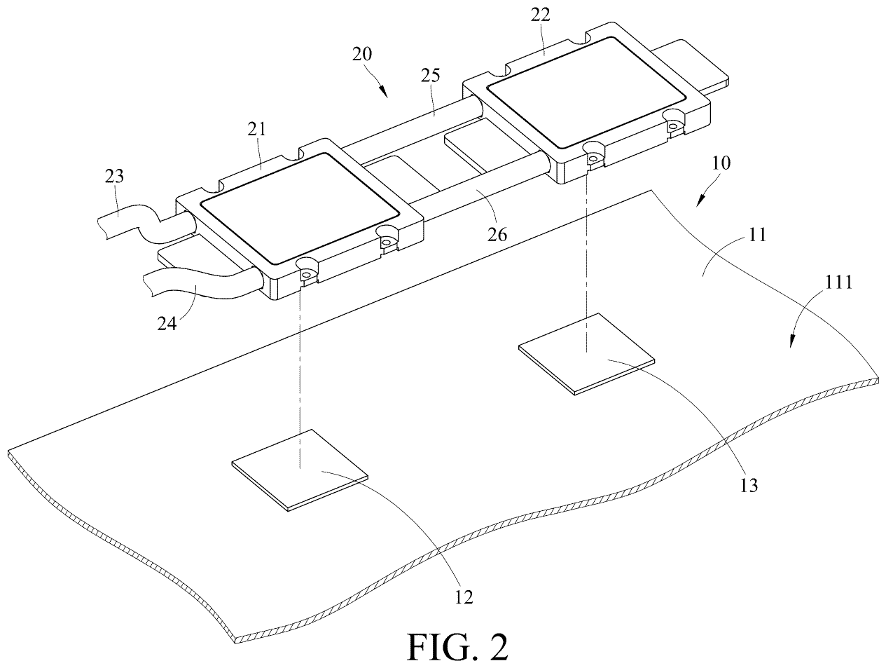

Referring to FIGS. 1 and 2, FIG. 1 is a perspective view of a motherboard module 1 according to some embodiments of the disclosure, and FIG. 2 is an exploded view of the motherboard module 1 according to some embodiments of the disclosure. The structural features of FIGS. 1 and 2 may be applied to other embodiments of the disclosure.

The motherboard module 1 is, for example, configured to be disposed in an internal space of a casing of an electronic device, where the electronic device is, for example, a server. The motherboard module 1 includes a motherboard 10 and a cold plate assembly 20.

The motherboard 10 includes a circuit board 11, a first heat source 12, and a second heat source 13 which are disposed on the circuit board 11. The first heat source 12 and the second heat source 13 may be, for example, a central processing unit or a graphics processing unit. In some embodiments, the first heat source 12 and the second heat source 13 are disposed on a same surface 111 of the circuit board 11.

The cold plate assembly 20 includes a first cold plate 21 and a second cold plate 22. The first cold plate 21 and the second cold plate 22 are thermally coupled to the first heat source 12 and the second heat source 13, respectively.

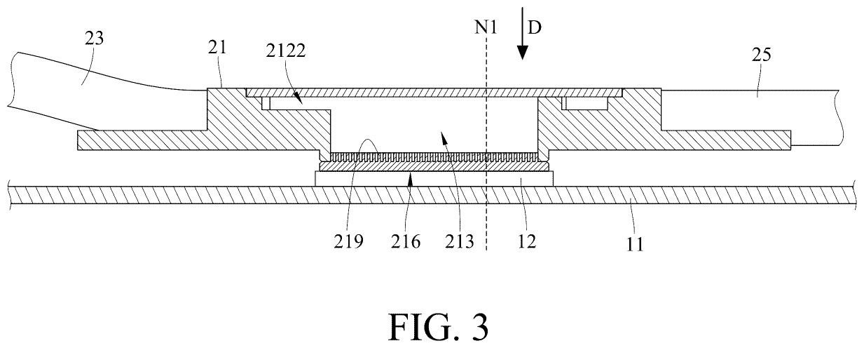

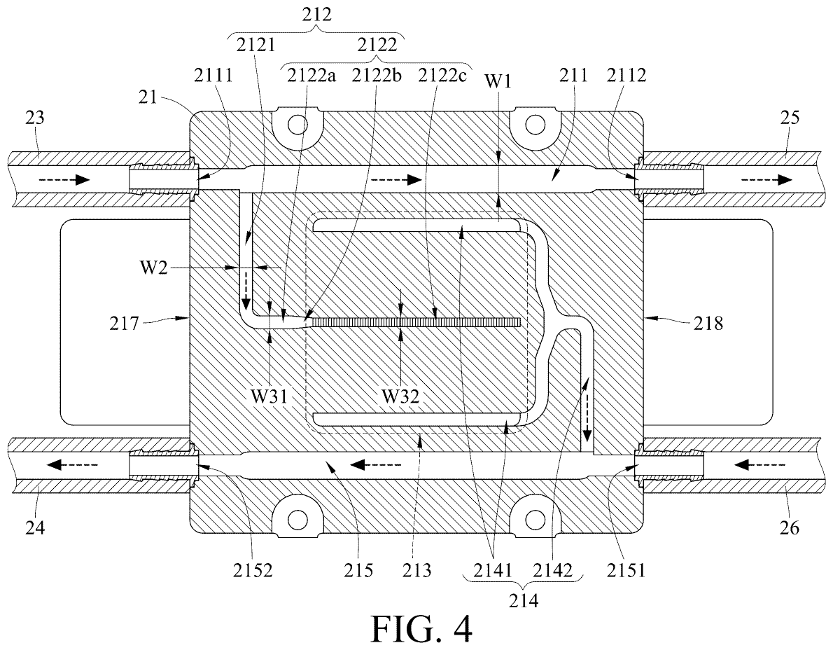

Then, referring to FIGS. 3 and 4, FIG. 3 is a partial cross-sectional view of the motherboard 10 and the first cold plate 21 according to some embodiments of the disclosure, and FIG. 4 is a cross-sectional view of the first cold plate 21 according to some embodiments of the disclosure. The structural features of FIGS. 3 and 4 may be applied to other embodiments of the disclosure.

The first cold plate 21 includes a main inlet channel 211, a sub-inlet channel 212, a heat exchange chamber 213, a sub-outlet channel 214, and a main outlet channel 215. The main inlet channel 211 has a cold fluid inlet 2111 and a cold fluid outlet 2112. The sub-inlet channel 212 is in fluid communication with the main inlet channel 211. The heat exchange chamber 213 is in fluid communication with the sub-inlet channel 212. The sub-outlet channel 214 is in fluid communication with the heat exchange chamber 213. The main outlet channel 215 is in fluid communication with the sub-outlet channel 214 and has a hot fluid inlet 2151 and a hot fluid outlet 2152. The first cold plate 21 forms a thermally coupling surface 216, which corresponds to the heat exchange chamber 213. In some embodiments, in a direction D perpendicular to the thermally coupling surface 216 (e.g., in a direction parallel to a normal line N1 of the thermally coupling surface 216), the main inlet channel 211 and the main outlet channel 215 are entirely non-overlapping with the heat exchange chamber 213.

The first cold plate 21 has a first side 217 and a second side 218 located opposite to each other. The cold fluid inlet 2111 of the main inlet channel 211 and the hot fluid outlet 2152 of the main outlet channel 215 are located on the first side 217 of the first cold plate 21. The cold fluid outlet 2112 of the main inlet channel 211 and the hot fluid inlet 2151 of the main outlet channel 215 are located on the second side 218 of the first cold plate 21.

In some embodiments, the cold plate assembly 20 may further include a main inlet pipe 23 and a main outlet pipe 24. The cold fluid inlet 2111 of the main inlet channel 211 and the hot fluid outlet 2152 of the main outlet channel 215 are respectively connected to the main inlet pipe 23 and the main outlet pipe 24.

In some embodiments, the cold plate assembly 20 may further include a first connecting pipe 25 and a second connecting pipe 26. The cold fluid outlet 2112 of the main inlet channel 211 of the first cold plate 21 is connected to the first connecting pipe 25, and the hot fluid inlet 2151 of the first cold plate 21 is connected to the second connecting pipe 26.

In some embodiments, in the direction D perpendicular to the thermally coupling surface 216, the sub-outlet channel 214 and the sub-inlet channel 212 overlap with the heat exchange chamber 213.

In some embodiments, the sub-inlet channel 212 includes a first inlet section 2121 and a second inlet section 2122. The first inlet section 2121 is in fluid communication with the main inlet channel 211, and the second inlet section 2122 is in fluid communication with the first inlet section 2121. The second inlet section 2122 is non-parallel to the first inlet section 2121. In some embodiments, the first inlet section 2121 is perpendicular to the main inlet channel 211, and the second inlet section 2122 is perpendicular to the first inlet section 2121.

In some embodiments, a width W1 of the main inlet channel 211 is greater than a width W2 of the first inlet section 2121 and a width of the second inlet section 2122 (e.g., widths W31 and W32).

In some embodiments, the second inlet section 2122 includes a wide portion 2122a, a tapered portion 2122b, and a narrow portion 2122c. The tapered portion 2122b is located between the wide portion 2122a and the narrow portion 2122c, and the tapered portion 2122b is in fluid communication with the wide portion 2122a and the narrow portion 2122c. The width W31 of the wide portion 2122a is greater than the width W32 of the narrow portion 2122c. The wide portion 2122a is in fluid communication with the first inlet section 2121, and the narrow portion 2122c is in fluid communication with the heat exchange chamber 213. In some embodiments, the thermally coupling surface 216 faces away from the heat exchange chamber 213, and the narrow portion 2122c is in fluid communication with one side of a central portion of the heat exchange chamber 213 located farther away from the thermally coupling surface 216. In some embodiments, from the view illustrated in FIG. 4, a portion of the sub-inlet channel 212 (e.g., the narrow portion 2122c) extends at the middle of the heat exchange chamber 213.

In some embodiments, the sub-outlet channel 214 includes two outlet sections 2141 and a convergence section 2142. The outlet sections 2141 are in fluid communication with the heat exchange chamber 213. One end of the convergence section 2142 is in fluid communication with the two outlet sections 2141, and the other end of the convergence section 2142 is in fluid communication with the main outlet channel 215. In some embodiments, the second inlet section 2122 (e.g., the narrow portion 2122c of the second inlet section 2122) is partially located between the two outlet sections 2141. One of the outlet sections 2141 is partially located between the main inlet channel 211 and the second inlet section 2122, and the other outlet section 2141 is partially located between the main outlet channel 215 and the second inlet section 2122.

In some embodiments, the cold fluid inlet 2111, the cold fluid outlet 2112, the hot fluid inlet 2151 and the hot fluid outlet 2152 are not projectively overlapping with the heat exchange chamber 213 from a top view of the first cold plate 21.

In some embodiments, the first cold plate 21 may further include a plurality of fins 219. The fins 219 are disposed in the heat exchange chamber 213 and extend in a direction from one of the two outlet sections 2141 toward the other.

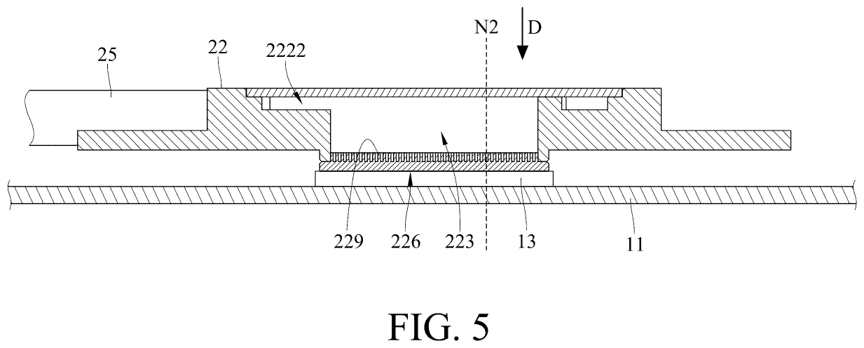

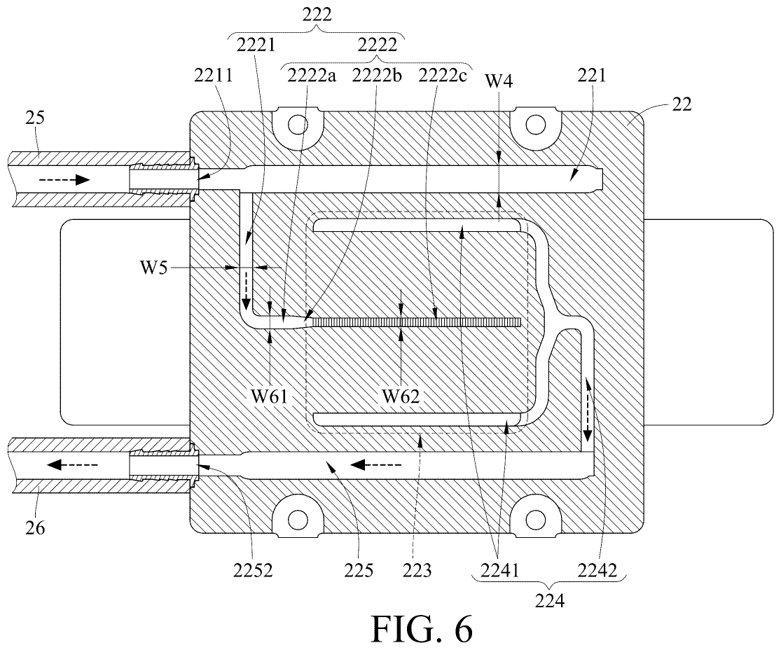

Then, referring to FIGS. 5 and 6, FIG. 5 is a partial cross-sectional view of the motherboard 10 and the second cold plate 22 according to some embodiments of the disclosure, and FIG. 6 is a cross-sectional view of the second cold plate 22 according to some embodiments of the disclosure. The structural features of FIGS. 5 and 6 may be applied to other embodiments of the disclosure.

The second cold plate 22 includes a main inlet channel 221, a sub-inlet channel 222, a heat exchange chamber 223, a sub-outlet channel 224, and a main outlet channel 225. The main inlet channel 221 has a cold fluid inlet 2211. The sub-inlet channel 222 is in fluid communication with the main inlet channel 221. The heat exchange chamber 223 is in fluid communication with the sub-inlet channel 222. The sub-outlet channel 224 is in fluid communication with the heat exchange chamber 223. The main outlet channel 225 is in fluid communication with the sub-outlet channel 224 and has a hot fluid outlet 2252. The second cold plate 22 forms a thermally coupling surface 226, which corresponds to the heat exchange chamber 223. In a direction D perpendicular to the thermally coupling surface 226 (e.g., in a direction parallel to a normal line N2 of the thermally coupling surface 226), the main inlet channel 221 and the main outlet channel 225 are entirely non-overlapping with the heat exchange chamber 223.

In some embodiments, the cold fluid inlet 2211 of the main inlet channel 221 and the hot fluid outlet 2252 of the main outlet channel 225 are located on a same side of the second cold plate 22.

In some embodiments, the cold fluid inlet 2211 of the main inlet channel 221 of the second cold plate 22 is connected to the first connecting pipe 25, and the hot fluid outlet 2252 of the second cold plate 22 is connected to the second connecting pipe 26. That is, the main inlet channel 211 of the first cold plate 21 (as shown in FIG. 4) is in fluid communication with the main inlet channel 221 of the second cold plate 22 through the first connecting pipe 25, and the main outlet channel 215 of the first cold plate 21 (as shown in FIG. 4) is in fluid communication with the main outlet channel 225 of the second cold plate 22 through the second connecting pipe 26.

In some embodiments, in the direction D perpendicular to the thermally coupling surface 226, the sub-outlet channel 224 and the sub-inlet channel 222 overlap with the heat exchange chamber 223.

In some embodiments, the sub-inlet channel 222 includes a first inlet section 2221 and a second inlet section 2222. The first inlet section 2221 is in fluid communication with the main inlet channel 221, and the second inlet section 2222 is in fluid communication with the first inlet section 2221. The second inlet section 2222 is non-parallel to the first inlet section 2221. In some embodiments, the first inlet section 2221 is perpendicular to the main inlet channel 221, and the second inlet section 2222 is perpendicular to the first inlet section 2221.

In some embodiments, a width W4 of the main inlet channel 221 is greater than a width W5 of the first inlet section 2221 and a width of the second inlet section 2222 (e.g., widths W61 and W62).

In some embodiments, the second inlet section 2222 includes a wide portion 2222a, a tapered portion 2222b, and a narrow portion 2222c. The tapered portion 2222b is located between the wide portion 2222a and the narrow portion 2222c, and the tapered portion 2222b is in fluid communication with the wide portion 2222a and the narrow portion 2222c. The width W61 of the wide portion 2222a is greater than the width W62 of the narrow portion 2222c. The wide portion 2222a is in fluid communication with the first inlet section 2221, and the narrow portion 2222c is in fluid communication with the heat exchange chamber 223. In some embodiments, the thermally coupling surface 226 faces away from the heat exchange chamber 223, and the narrow portion 2222c is in fluid communication with one side of a central portion of the heat exchange chamber 223 located farther away from the thermally coupling surface 226.

In some embodiments, the sub-outlet channel 224 includes two outlet sections 2241 and a convergence section 2242. The outlet sections 2241 are in fluid communication with the heat exchange chamber 223. One end of the convergence section 2242 is in fluid communication with the two outlet sections 2241, and the other end of the convergence section 2242 is in fluid communication with the main outlet channel 225. In some embodiments, the second inlet section 2222 (e.g., the narrow portion 2222c of the second inlet section 2222) is partially located between the two outlet sections 2241. One of the outlet sections 2241 is partially located between the main inlet channel 221 and the second inlet section 2222, and the other outlet section 2241 is partially located between the main outlet channel 225 and the second inlet section 2222.

In some embodiments, the second cold plate 22 may further include a plurality of fins 229. The fins 229 are disposed in the heat exchange chamber 223 and extend in direction from one of the two outlet sections 2241 toward the other.

In some embodiments, a minimum width of the sub-inlet channel 212 (e.g., the width W32 of the narrow portion 2122c) of the first cold plate 21 is smaller than a minimum width of the sub-inlet channel 222 (e.g., the width W62 of the narrow portion 2222c) of the second cold plate 22.

Next, the flow process of a coolant in the cold plate assembly 20 will be described with reference to FIGS. 4 and 6, where dashed arrows indicate the flow direction of the coolant. In the above embodiments, the low-temperature coolant (not shown) enters the main inlet channel 211 of the first cold plate 21 through the main inlet pipe 23, so that a portion of the low-temperature coolant flows into the heat exchange chamber 213 through the sub-inlet channel 212 and exchanges heat with the fins 219 in the heat exchange chamber 213. Another portion of the low-temperature coolant flows into the main inlet channel 221 of the second cold plate 22 through the first connecting pipe 25, and then flows into the heat exchange chamber 223 through the sub-inlet channel 222 to exchange heat with the fins 229 in the heat exchange chamber 223.

The high-temperature coolant flowing out of the heat exchange chamber 223 of the second cold plate 22 passes through the sub-outlet channel 224 to reach the main outlet channel 225, and then flows into the main outlet channel 215 of the first cold plate 21 through the second connecting pipe 26. The high-temperature coolant flowing out of the heat exchange chamber 213 of the first cold plate 21 passes through the sub-outlet channel 214 to reach the main outlet channel 215, where it converges with the high-temperature coolant from the second cold plate 22. The converged high-temperature coolant then flows from the main outlet channel 215 of the first cold plate 21 to the main outlet pipe 24, and subsequently flows through a pipeline (not shown) to a radiator (not shown) for being cooled.

In the above embodiments, the first cold plate 21 has the first side 217 and the second side 218 located opposite to each other, the cold fluid inlet 2111 of the main inlet channel 211 and the hot fluid outlet 2152 of the main outlet channel 215 are located on the first side 217 of the first cold plate 21, and the cold fluid outlet 2112 of the main inlet channel 211 and the hot fluid inlet 2151 of the main outlet channel 215 are located on the second side 218 of the first cold plate 21. The aforementioned configuration can reduce the overall height of the first cold plate 21, making it suitable for installation within an internal space of the server. Similarly, the configuration in which the cold fluid inlet 2211 of the main inlet channel 221 and the hot fluid outlet 2252 of the main outlet channel 225 of the second cold plate 22 are located on the same side can reduce the overall height of the second cold plate 22, making it suitable for installation within the internal space of the server.

In one embodiment, the main inlet channel of the second cold plate may also have a cold fluid outlet (not shown), and the main outlet channel of the second cold plate may also have a hot fluid inlet (not shown), where the cold fluid outlet and the hot fluid inlet of the second cold plate located on a same side so as to be connected to another cold plate. That is, the second cold plate may have the same structure as the first cold plate.

In addition, in the direction perpendicular to the thermally coupling surface of the cold plate, the main inlet channel and the main outlet channel of the cold plate are entirely non-overlapping with the heat exchange chamber, and the main inlet channel and the main outlet channel are respectively in fluid communication with the heat exchange chamber through the sub-inlet channel and the sub-outlet channel. The aforementioned configuration can further reduce the overall height of the cold plate, making it suitable for installation within the internal space of the server. For example, compared to a cold plate with a T-shaped connector at the top, the overall height of the first cold plate 21 (or the second cold plate 22) in the aforementioned embodiment can be reduced from 24.78 mm to 19.15 mm, while simulations show that their heat exchange performance is similar.

In addition, the width W1 of the main inlet channel 211 is greater than the width W2 of the first inlet section 2121 and the width of the second inlet section 2122 (e.g., the widths W31 and W32), the tapered portion 2122b of the second inlet section 2122 is located between the wide portion 2122a and the narrow portion 2122c, and the width W31 of the wide portion 2122a is greater than the width W32 of the narrow portion 2122c. By the aforementioned configuration, the pressure drop of the coolant flowing through the main inlet channel 211 and the sub-inlet channel 212 can be adjusted. Similarly, the width design of the main inlet channel 221 and the sub-inlet channel 222 of the second cold plate 22 can achieve the same effect.

Furthermore, the minimum width of the sub-inlet channel 212 (e.g., the width W32 of the narrow portion 2122c) of the first cold plate 21 is smaller than the minimum width of the sub-inlet channel 222 (e.g., the width W62 of the narrow portion 2222c) of the second cold plate 22. By the aforementioned configuration, the pressure drop of the coolant flowing through the sub-inlet channel 212 of the first cold plate 21 is greater than that of the coolant flowing through the sub-inlet channel 222 of the second cold plate 22. In this way, the coolant can flow evenly through both the first cold plate 21 and the second cold plate 22.

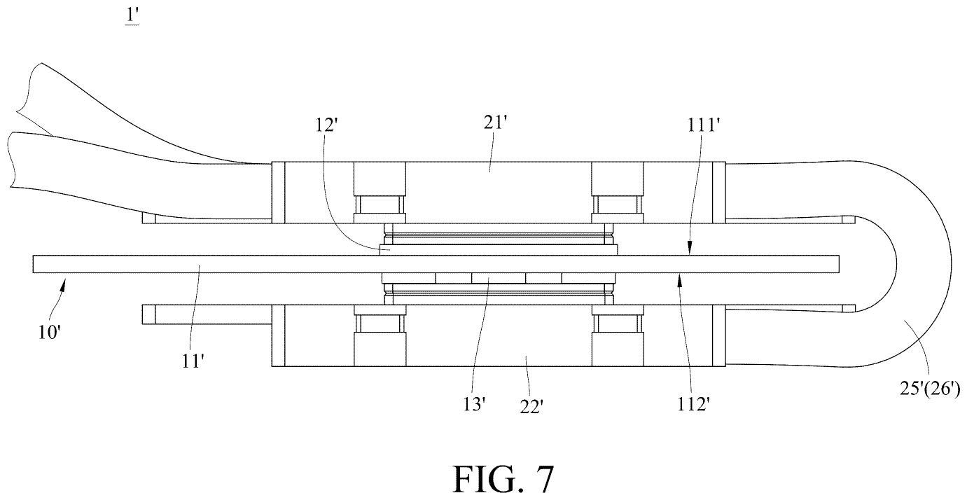

Then, referring to FIG. 7, FIG. 7 is a side view of a motherboard module 1′ according to some embodiments of the disclosure.

The motherboard module 1′ in this embodiment is similar to the motherboard module 1 in the embodiment of FIG. 1. The following mainly describes the differences between them, and the same parts will not be repeated hereinafter.

In some embodiments, a first heat source 12′ and a second heat source 13′ of a motherboard 10′ are disposed on two opposite surfaces 111′ and 112′ of a circuit board 11′, respectively. The first heat source 12′ may be, for example, a central processing unit or a graphics processing unit. The second heat source 13′ may be, for example, a voltage regulator. A first connecting pipe 25′ and a second connecting pipe 26′ are flexible hoses. The first connecting pipe 25′ and the second connecting pipe 26′ are bent around an edge of the circuit board 11′ to connect a first cold plate 21′ and a second cold plate 22′ located on the two opposite surfaces 111′ and 112′ of the circuit board 11′.

In the embodiment of FIG. 7, even though the first heat source 12′ and the second heat source 13′ are disposed on the two opposite surfaces 111′ and 112′ of the circuit board 11′, because the overall heights of the first cold plate 21′ and the second cold plate 22′ are reduced compared to a cold plate with a T-shaped connector at the top, the motherboard module 1′ can still fit within the internal space of the server.

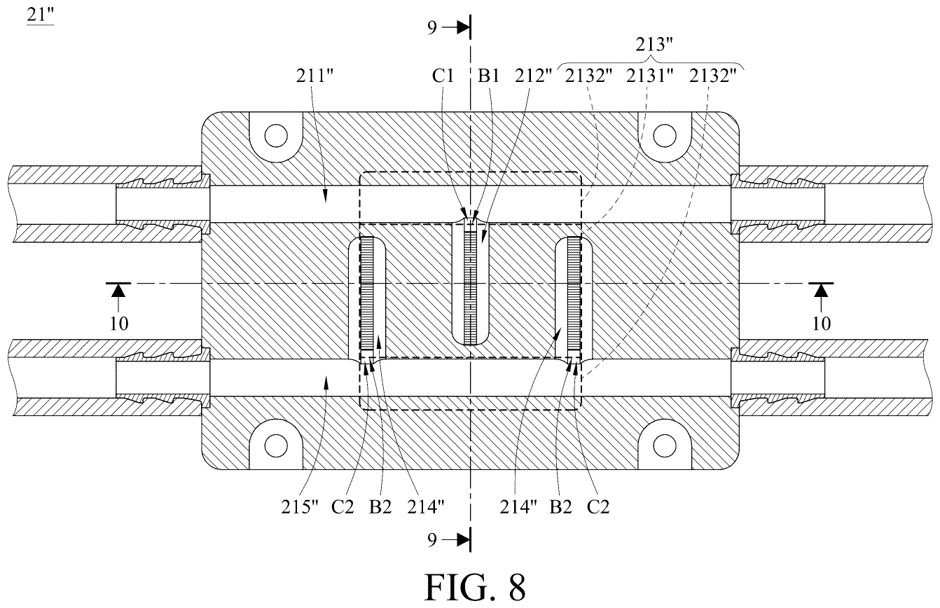

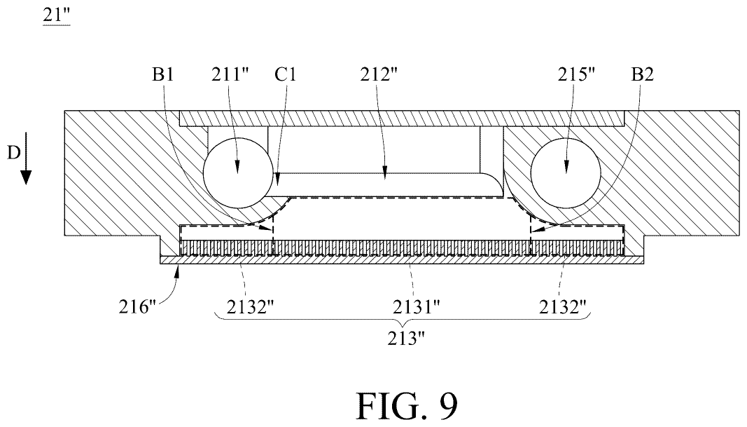

In the above embodiments, in the direction perpendicular to the thermally coupling surface, the main inlet channel and the main outlet channel of the cold plate are entirely non-overlapping with the heat exchange chamber; however, the disclosure is not limited thereto. Referring to FIGS. 8 and 9, FIG. 8 is a cross-sectional view of a cold plate 21″ according to some embodiments of the disclosure, and FIG. 9 is another cross-sectional view of the cold plate 21″ according to some embodiments of the disclosure, where FIG. 9 is drawn along a line 9-9 in FIG. 8. The structural features of FIGS. 8 and 9 may be applied to other embodiments of the disclosure.

The cold plate 21″ in this embodiment is similar to the first cold plate 21 in the embodiment of FIG. 4. The following mainly describes the differences between them, and the same parts will not be repeated hereinafter.

In some embodiments, in a direction D perpendicular to a thermally coupling surface 216″ of the cold plate 21″, a main inlet channel 211″ and a main outlet channel 215″ of the cold plate 21″ do not overlap with a central portion 2131″ of a heat exchange chamber 213″. For example, the main inlet channel 211″ and the main outlet channel 215″ of the cold plate 21″ overlap with two outer portions 2132″ of the heat exchange chamber 213″ located on two opposite sides of the central portion 2131″. In some embodiments, the central portion 2131″ encompasses the geometric center of the heat exchange chamber 213″.

In some embodiments, the main inlet channel 211″ of the cold plate 21″ is in fluid communication with the heat exchange chamber 213″ through a sub-inlet channel 212″, and a junction C1 between the sub-inlet channel 212″ and the main inlet channel 211″ is located at a boundary B1 on one side of the central portion 2131″.

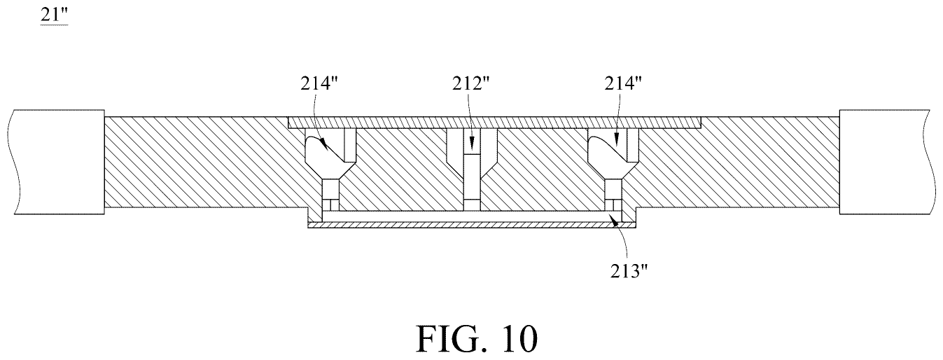

Referring to FIGS. 8 and 10, FIG. 10 is another cross-sectional view of the cold plate 21″ according to some embodiments of the disclosure, where FIG. 10 is drawn along a line 10-10 in FIG. 8. In some embodiments, the cold plate 21″ may include two sub-outlet channels 214″, the two sub-outlet channels 214″ are located on two opposite sides of the sub-inlet channel 212″. In some embodiments, the sub-inlet channel 212″ is located between the two sub-outlet channels 214″ from a top view of the cold plate 21″. The main outlet channel 215″ is in fluid communication with the heat exchange chamber 213″ through the two sub-outlet channels 214″, and junctions C2 between the main outlet channel 215″ and the two sub-outlet channels 214″ are located at a boundary B2 on another side of the central portion 2131″.

According to the cold plate, the cold plate assembly and the motherboard module as discussed in the above embodiments, the cold plate has the first side and the second side located opposite to each other, the cold fluid inlet of the main inlet channel and the hot fluid outlet of the main outlet channel are located on the first side of the cold plate, and the cold fluid outlet of the main inlet channel and the hot fluid inlet of the main outlet channel are located on the second side of the cold plate. The aforementioned configuration can reduce the overall height of the cold plate, making it suitable for installation within an internal space of the server.

In addition, in the direction perpendicular to the thermally coupling surface of the cold plate, the main inlet channel and the main outlet channel of the cold plate are entirely non-overlapping with the heat exchange chamber, and the main inlet channel and the main outlet channel are respectively in fluid communication with the heat exchange chamber through the sub-inlet channel and the sub-outlet channel. The aforementioned configuration can further reduce the overall height of the cold plate, making it suitable for installation within the internal space of the server.

Furthermore, the width of the main inlet channel is greater than the width of the first inlet section and the width of the second inlet section, the tapered portion of the second inlet section is located between the wide portion and the narrow portion, and the width of the wide portion is greater than the width of the narrow portion. By the aforementioned configuration, the pressure drop of the coolant flowing through the main inlet channel and the sub-inlet channel can be adjusted.

Moreover, the minimum width of the sub-inlet channel of the first cold plate is smaller than the minimum width of the sub-inlet channel of the second cold plate. By the aforementioned configuration, the pressure drop of the coolant flowing through the sub-inlet channel of the first cold plate is greater than that of the coolant flowing through the sub-inlet channel of the second cold plate. In this way, the coolant can flow evenly through both the first cold plate and the second cold plate.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A cold plate, comprising:
a main inlet channel, having a cold fluid inlet and a cold fluid outlet;
a sub-inlet channel, in fluid communication with the main inlet channel;
a heat exchange chamber, in fluid communication with the sub-inlet channel;
at least one sub-outlet channel, in fluid communication with the heat exchange chamber; and
a main outlet channel, in fluid communication with the at least one sub-outlet channel and having a hot fluid inlet and a hot fluid outlet;
wherein the cold plate has a first side and a second side located opposite to each other, the cold fluid inlet of the main inlet channel and the hot fluid outlet of the main outlet channel are located on the first side of the cold plate, and the cold fluid outlet of the main inlet channel and the hot fluid inlet of the main outlet channel are located on the second side of the cold plate.

2. The cold plate according to claim 1, wherein the cold plate forms a thermally coupling surface corresponding to the heat exchange chamber; in a direction perpendicular to the thermally coupling surface, the main inlet channel and the main outlet channel do not overlap with a central portion of the heat exchange chamber.

3. The cold plate according to claim 2, wherein, in the direction perpendicular to the thermally coupling surface, the main inlet channel and the main outlet channel are entirely non-overlapped with the heat exchange chamber.

4. The cold plate according to claim 2, wherein, in the direction perpendicular to the thermally coupling surface, the at least one sub-outlet channel and the sub-inlet channel overlap with the heat exchange chamber.

5. The cold plate according to claim 1, wherein the sub-inlet channel comprises a first inlet section and a second inlet section, the first inlet section is in fluid communication with the main inlet channel, the second inlet section is in fluid communication with the first inlet section, and the second inlet section is non-parallel to the first inlet section.

6. The cold plate according to claim 5, wherein a width of the main inlet channel is greater than a width of the first inlet section and a width of the second inlet section.

7. The cold plate according to claim 5, wherein the second inlet section comprises a wide portion, a tapered portion and a narrow portion, the tapered portion is located between and in fluid communication with the wide portion and the narrow portion, a width of the wide portion is greater than a width of the narrow portion, the wide portion is in fluid communication with the first inlet section, and the narrow portion is in fluid communication with the heat exchange chamber.

8. The cold plate according to claim 7, wherein the cold plate forms a thermally coupling surface, the thermally coupling surface faces away from the heat exchange chamber, and the narrow portion is in fluid communication with one side of the heat exchange chamber located farther away from the thermally coupling surface.

9. The cold plate according to claim 7, wherein the narrow portion is in fluid communication with a central portion of the heat exchange chamber.

10. The cold plate according to claim 5, wherein the at least one sub-outlet channel comprises two outlet sections and a convergence section, the two outlet sections are in fluid communication with the heat exchange chamber, one end of the convergence section is in fluid communication with the two outlet sections, and the other end of the convergence section is in fluid communication with the main outlet channel.

11. The cold plate according to claim 10, wherein the second inlet section is partially located between the two outlet sections, one of the two outlet sections is partially located between the main inlet channel and the second inlet section, and the other of the two outlet sections is partially located between the main outlet channel and the second inlet section.

12. The cold plate according to claim 5, wherein the first inlet section is perpendicular to the main inlet channel, and the second inlet section is perpendicular to the first inlet section.

13. The cold plate according to claim 2, wherein a junction between the sub-inlet channel and the main inlet channel is located at a boundary on one side of the central portion of the heat exchange chamber.

14. The cold plate according to claim 1, wherein the cold fluid inlet, the cold fluid outlet, the hot fluid inlet and the hot fluid outlet are not projectively overlapping with the heat exchange chamber.

15. The cold plate according to claim 1, wherein the at least one sub-outlet channel of the cold plate comprises two sub-outlet channels, the sub-inlet channel is located between the two sub-outlet channels.

16. The cold plate according to claim 1, wherein a portion of the sub-inlet channel extends at the middle of the heat exchange chamber.

17. A cold plate assembly, comprising:
a first cold plate and a second cold plate, each comprising:
a main inlet channel, having a cold fluid inlet and a cold fluid outlet;
a sub-inlet channel, in fluid communication with the main inlet channel;
a heat exchange chamber, in fluid communication with the sub-inlet channel;
a sub-outlet channel, in fluid communication with the heat exchange chamber; and
a main outlet channel, in fluid communication with the sub-outlet channel and having a hot fluid inlet and a hot fluid outlet;
wherein each of the first cold plate and the second cold plate has a first side and a second side located opposite to each other; the cold fluid inlet of the main inlet channel and the hot fluid outlet of the main outlet channel are located on the first side, and the cold fluid outlet of the main inlet channel and the hot fluid inlet of the main outlet channel are located on the second side;
wherein the main inlet channel of the first cold plate is in fluid communication with the main inlet channel of the second cold plate, and the main outlet channel of the first cold plate is in fluid communication with the main outlet channel of the second cold plate.

18. The cold plate assembly according to claim 17, further comprising a main inlet pipe and a main outlet pipe, wherein the main inlet pipe is in fluid communication with the main inlet channel of the first cold plate, and the main outlet pipe is in fluid communication with the main outlet channel of the first cold plate.

19. The cold plate assembly according to claim 18, wherein a minimum width of the sub-inlet channel of the first cold plate is smaller than a minimum width of the sub-inlet channel of the second cold plate.

20. The cold plate assembly according to claim 17, further comprises a first connecting pipe and a second connecting pipe, wherein the main inlet channel of the first cold plate is in fluid communication with the main inlet channel of the second cold plate through the first connecting pipe, and the main outlet channel of the first cold plate is in fluid communication with the main outlet channel of the second cold plate through the second connecting pipe.

21. A motherboard module, comprising:
a motherboard, comprising a circuit board, a first heat source and a second heat source which are disposed on the circuit board; and
a cold plate assembly, comprising:
a first cold plate and a second cold plate, respectively thermally coupled to the first heat source and the second heat source, wherein each of the first cold plate and the second cold plate comprises:
a main inlet channel, having a cold fluid inlet and a cold fluid outlet;
a sub-inlet channel, in fluid communication with the main inlet channel;
a heat exchange chamber, in fluid communication with the sub-inlet channel;
a sub-outlet channel, in fluid communication with the heat exchange chamber; and
a main outlet channel, in fluid communication with the sub-outlet channel and having a hot fluid inlet and a hot fluid outlet;
wherein each of the first cold plate and the second cold plate has a first side and a second side located opposite to each other; the cold fluid inlet of the main inlet channel and the hot fluid outlet of the main outlet channel are located on the first side, and the cold fluid outlet of the main inlet channel and the hot fluid inlet of the main outlet channel are located on the second side;
wherein the main inlet channel of the first cold plate is in fluid communication with the main inlet channel of the second cold plate, and the main outlet channel of the first cold plate is in fluid communication with the main outlet channel of the second cold plate.

22. The motherboard module according to claim 21, wherein the cold plate assembly further comprises a first connecting pipe and a second connecting pipe, the main inlet channel of the first cold plate is in fluid communication with the main inlet channel of the second cold plate through the first connecting pipe, and the main outlet channel of the first cold plate is in fluid communication with the main outlet channel of the second cold plate through the second connecting pipe.

23. The motherboard module according to claim 22, wherein the first heat source and the second heat source are disposed on a same surface of the circuit board.

24. The motherboard module according to claim 22, wherein the first heat source and the second heat source are respectively disposed on two opposite surfaces of the circuit board.

25. The motherboard module according to claim 24, wherein the first connecting pipe and the second connecting pipe are flexible hoses.
